(19) United States
(12) Patent Application Publication
(10) Pub. No.: US 2026/0334244 A1
(43) Pub. Date: Oct. 22, 2026

(54) METHOD FOR MANUFACTURING GLASS SUBSTRATE WITH THROUGH-HOLE, AND GLASS SUBSTRATE WITH THROUGH-HOLE

(71) Applicant: AGC INC., Tokyo (JP)

(72) Inventors: Kaede OKAMOTO, Tokyo (JP); Kohei HORIUCHI, Tokyo (JP)

(73) Assignee: AGC INC., Tokyo (JP)

(21) Appl. No.: 19/468,760

(22) Filed: Feb. 3, 2026

Related U.S. Application Data
(63) Continuation of application No. PCT/JP2024/026453, filed on Jul. 24, 2024.

(30) Foreign Application Priority Data
Aug. 8, 2023 (JP) 2023-128955

(51) Int. Cl. H10W 70/05; C03C 15/00; C03C 23/00; H10W 70/63; H10W 70/692

(52) U.S. Cl. CPC H10W 70/095; C03C 15/00; C03C 23/0025; H10W 70/635; H10W 70/692

(57) ABSTRACT

A method includes: a step of forming an initial through-hole in a glass substrate having a first surface and a second surface by applying laser light to the glass substrate from a first surface side thereof, the initial through-hole including a first initial opening on the first surface and including a second initial opening on the second surface; a step of performing first wet etching for the glass substrate at an etching rate in a range of 0.04 μm/min to 0.20 μm/min in a state in which a masking material is disposed so as to close the initial opening of the initial through-hole having a larger diameter, and thereby forming a first through-hole from the initial through-hole; and a step of performing second wet etching for the glass substrate in a state in which the masking material has been removed.

### INCORPORATION BY REFERENCE

This application is based upon and claims the benefit of priority from Japanese patent application No. 2023-128955 filed on Aug. 8, 2023, and PCT application No. PCT/JP2024/026453 filed on Jul. 24, 2024, the disclosure of which is incorporated herein in its entirety by reference.

### BACKGROUND

The present invention relates to a method for manufacturing a glass substrate with a through-hole, and a glass substrate with a through-hole.

A technique for forming a through-hole in a glass substrate by irradiating the glass substrate with laser light has been known from the past.

For example, Japanese Unexamined Patent Application Publication No. 2016-113358 discloses a method for forming a through-hole in a glass substrate by using a CO₂ laser.

### SUMMARY

In techniques for forming a through-hole in a glass substrate like the one described above, there is often a problem that a through-hole having a desired shape cannot be formed.

For example, in a conventional method, one surface of a processed through-hole may be inclined toward another surface thereof (i.e., the so-called “tapered shape” is formed), or a narrowed part and a bulge (hereinafter also collectively referred to as “non-straight parts”) are formed along the extending direction of the through-hole.

When such a through-hole having a shape deviated from a predetermined shape is formed in a glass substrate, it may become difficult to properly fill the through-hole with a conductive material in the subsequent step. Further, when such a glass substrate in which a through-hole is unevenly filled with a conductive material is used and an electric current is fed thereto, an energy loss may occur.

The present invention has been made in view of the above-described background, and an object thereof is to provide a method for manufacturing a glass substrate with a through-hole, capable of forming a through-hole having a shape closer to a desired shape. Further, another object of the present invention is to provide a glass substrate including a through-hole having a shape closer to a desired shape.

According to the present invention, a method for manufacturing a glass substrate with a through-hole comprises:
(1) a step of forming an initial through-hole in a glass substrate having a first surface and a second surface by applying laser light to the glass substrate from a first surface side thereof, the initial through-hole including a first initial opening on the first surface and including a second initial opening on the second surface;
(2) a step of performing first wet etching for the glass substrate at a first etching rate in a state in which a masking material is disposed so as to close one of the first and second initial openings of the initial through-hole that has a larger diameter, and thereby forming a first through-hole from the initial through-hole, the first etching rate being in a range of 0.04 μm/min to 0.20 μm/min; and
(3) a step of performing second wet etching for the glass substrate in a state in which the masking material has been removed, and thereby forming a second through-hole from the first through-hole.

Further, according to the present invention, a glass substrate with a through-hole comprises:
a glass substrate having a first surface and a second surface opposite to each other; and
at least one through-hole extending from the first surface of the glass substrate to the second surface thereof, wherein
the glass substrate has a thickness in a range of 0.05 mm to 1.2 mm,
the through-hole includes a first opening having a diameter φ1 on the first surface of the glass substrate and includes a second opening having a diameter φ₂ on the second surface,
an absolute value of a difference Δφ between the diameter φ₁ of the first opening and the diameter φ₂ of the second opening is 5 μm or smaller,
in the through-hole, a position at which a size of a cross section perpendicular to an extension axis of the through-hole is a minimum is referred to as a constricted part,
in cross section of the through-hole along the extension axis thereof,
when one of ends of the first opening is referred to as a first end P_{1A}; the other end is referred to as a second end P_{1B}; an end of the second opening on the same side as the first end Pia is referred to as a third end P_{2A}; an end of the second opening on the same side as the second end P_{1B} is referred to as a fourth end P_{2B}; an end of the constricted part on the same side as the first end Pia is referred to as a fifth end P_{mA}; and an end of the constricted part on the same side as the second end P_{1B} is referred to as a sixth end P_{mB},
a line segment connecting the first end P_{1A} and the fifth end P_{mA} is referred to as a line segment LIA; a line segment connecting the second end P_{1B} and the sixth end P_{mB} is referred to as a line segment L_{1B}; a line segment connecting the third end P_{2A} and the fifth end P_{mA} is referred to as a line segment L_{2A}; and a line segment connecting the fourth end P_{2B} and the sixth end P_{mB} is referred to as a line segment L_{2B},
a perpendicular line is drawn from the first end P_{1A} toward inside of the glass substrate, and an angle formed between this perpendicular line and the line segment L_{1A} is referred to as a first upper taper angle θ_{1fu};
a perpendicular line is drawn from the second end P_{1B} toward inside of the glass substrate, and an angle formed between this perpendicular line and the line segment L_{1B} is referred to as a second upper taper angle θ_{2fu};
a perpendicular line is drawn from the third end P_{2A} toward inside of the glass substrate, and an angle formed between this perpendicular line and the line segment L_{2A} is referred to as a first lower taper angle θ_{1d};
a perpendicular line is drawn from the fourth end P_{2B} toward inside of the glass substrate, and an angle formed between this perpendicular line and the line segment L_{2B} is referred to as a second lower taper angle θ_{2fa}, and
an average of θ_{1fu}, θ_{2fu}, θ_{1fd}, and θ_{2fd} is referred to as a taper angle θₐᵥₑ,
this taper angle θₐᵥₑ is smaller than 4°,
in the cross section along the extension axis of the second through-hole,
when a sidewall part between the first end P_{1A} and the fifth end P_{mA} is referred to as a first sidewall; a sidewall part between the second end P_{1B} and the sixth end P_{mB} is referred to as a second sidewall; a sidewall part between the third end P_{2A} and the fifth end P_{mA} is referred to as a third sidewall; and a sidewall part between the fourth end P_{2B} and the sixth end P_{mB} is referred to as a fourth sidewall, and
a maximum value of a distance between the first sidewall and the line segment L_{1A} is referred to as a bulge B₁; a maximum value of a distance between the second sidewall and the line segment L_{1B} is referred to as a bulge B₂; a maximum value of a distance between the third sidewall and the line segment L_{2A} is referred to as a bulge B₃; a maximum value of a distance between the fourth sidewall and the line segment L_{2B} is referred to as a bulge B₄; and a bulge having a maximum value among the bulges B₁ to B₄ is referred to as a bulge Bₘₐₓ,
this maximum bulge Bₘₐₓ is 5 μm or smaller, and
when a distance from the first opening of the through-hole in a depth direction is represented by x (μm), and surface roughness (maximum height Rz) of a sidewall of the through-hole is represented by Q (μm), a relationship between Q and x can be approximated by

Q=mx+b Formula (1)
where m is an inclination in
(a) a range of −0.001 to −0.005, or
(b) a range of 0.001 to 0.005.

According to the present invention, it is possible to provide a method for manufacturing a glass substrate with a through-hole, capable of forming a through-hole having a shape closer to a desired shape. Further, according to the present invention, it is possible to provide a glass substrate including a through-hole having a shape closer to a desired shape.

The above and other objects, features and advantages of the present disclosure will become more fully understood from the detailed description given hereinbelow and the accompanying drawings.

### BRIEF DESCRIPTION OF DRAWINGS

FIG. 1 schematically shows a flow of a method for manufacturing a glass substrate with a through-hole according to an embodiment of the present invention;

FIG. 2 schematically shows a cross section of the glass substrate in one process in the method according to the embodiment of the present invention;

FIG. 3 schematically shows a cross section of the glass substrate in one process in the method according to the embodiment of the present invention;

FIG. 4 schematically shows a cross section of the glass substrate in one process in the method according to the embodiment of the present invention;

FIG. 5 schematically shows a cross section of the glass substrate in one process in the method according to the embodiment of the present invention;

FIG. 6 schematically shows an enlarged view of a cross section of a processed through-hole formed by a method according to an embodiment of the present invention along an extension axis L thereof;

FIG. 7 schematically shows an enlarged view of a cross section of a processed through-hole formed by a method according to an embodiment of the present invention along an extension axis L thereof;

FIG. 8 schematically shows an enlarged view of a cross section of a processed through-hole formed by a method according to an embodiment of the present invention along an extension axis L thereof;

FIG. 9 schematically shows an example of a cross section of a glass substrate with a through-hole according to an embodiment of the present invention;

FIG. 10 is a photograph showing an example of a cross-sectional form of a first through-hole obtained by an embodiment (Example 1) of the present invention;

FIG. 11 is a photograph showing an example of a cross-sectional form of a first through-hole obtained by another embodiment (Example 2) of the present invention;

FIG. 12 is a photograph showing an example of a cross-sectional form of a first through-hole obtained by yet another embodiment (Example 3) of the present invention;

FIG. 13 is a photograph showing an example of a cross-sectional form of a first through-hole obtained by a comparative example (Example 21);

FIG. 14 is a photograph showing an example of a cross-sectional form of a first through-hole obtained by a comparative example (Example 22);

FIG. 15 is a photograph showing an example of a cross-sectional form of a second through-hole obtained by an embodiment (Example 1) of the present invention;

FIG. 16 is a photograph showing an example of a cross-sectional form of a second through-hole obtained by an embodiment (Example 2) of the present invention;

FIG. 17 is a photograph showing an example of a cross-sectional form of a second through-hole obtained by a comparative example (Example 22);

FIG. 18 is a graph showing a relationship between the depth position on a sidewall of a through-hole obtained in a glass substrate with a through-hole (Sample 1) according to an embodiment of the present invention and the surface roughness thereof;

FIG. 19 is a graph showing a relationship between the depth position on a sidewall of a through-hole obtained in a glass substrate with a through-hole (Sample 23) in related art and the surface roughness thereof;

FIG. 20 is a photograph showing an example of a cross section of a second through-hole in a glass substrate with a through-hole (Sample 1) according to an embodiment of the present invention, taken by a laser microscope; and

FIG. 21 is a photograph showing an example of a cross section of a second through-hole in a glass substrate with a through-hole (Sample 23) in related art, taken by a laser microscope.

### DESCRIPTION OF EMBODIMENTS

Embodiments according to the present invention will be described hereinafter with reference to the drawings.

As described above, regarding glass substrates with through-holes in the past, a through-hole having a “tapered shape” and/or a through-hole having a “non-straight part” are found. When such a through-hole having a shape deviated from a predetermined shape is formed, it may become difficult to properly fill the through-hole with a conductive material in the subsequent process. Further, when such a glass substrate in which a through-hole is unevenly filled with a conductive material is used and an electric current is fed thereto, an energy loss may occur.

In contrast to this, in an embodiment according to the present invention,
a method for manufacturing a glass substrate with a through-hole comprises:
   (1) a step of forming an initial through-hole in a glass substrate having a first surface and a second surface by applying laser light to the glass substrate from a first surface side thereof, the initial through-hole including a first initial opening on the first surface and including a second initial opening on the second surface;
   (2) a step of performing first wet etching for the glass substrate at a first etching rate in a state in which a masking material is disposed so as to close one of the first and second initial openings of the initial through-hole that has a larger diameter, and thereby forming a first through-hole from the initial through-hole, the first etching rate being in a range of 0.04 μm/min to 0.20 μm/min; and
   (3) a step of performing second wet etching for the glass substrate in a state in which the masking material has been removed, and thereby forming a second through-hole from the first through-hole.

In the method according to an embodiment of the present invention, after an initial through-hole is formed by laser processing, first wet etching is performed for the glass substrate. Further, in this step, a masking material is disposed in one of the first and second initial openings of the initial through-hole that has a larger diameter (e.g., in the first initial opening).

When the first wet etching is performed in such a state, the etchant is fed (i.e., flows) into the through-hole from the initial opening having the small diameter. Therefore, it is possible to increase the amount of the etching on the side of the glass substrate on which the initial opening having the small diameter is located, and as a result, it is possible to reduce the difference between the diameters of the openings on both sides in the obtained first through-hole. In this way, it is possible to significantly prevent the first through-hole from having a “tapered shape”.

Further, non-straight parts such as “narrowed parts” and “bulges” are also significantly reduced by the first wet etching.

Note that if the etching rate in the first wet etching is too high, problems such as formation of a “non-straight part” and an increase in the taper angle may occur.

However, in an embodiment according to the present invention, the etching rate of the first wet etching is adjusted to a range of 0.04 μm/min to 0.20 μm/min, i.e., adjusted to a relatively low etching rate. Therefore, the above-described problems are also avoided.

After that, the overall size of the first through-hole is adjusted by second wet etching, and a second through-hole is thereby formed.

As a result of the above-described effects, in an embodiment according to the present invention, a first through-hole having a shape closer to a desired shape can be formed, and a second through-hole can be eventually formed.

(Method for Manufacturing Glass Substrate with Through-Hole According to Embodiment of Present Invention)

A method for manufacturing a glass substrate with a through-hole according to an embodiment of the present invention will be described hereinafter in a more detailed manner with reference to the drawings.

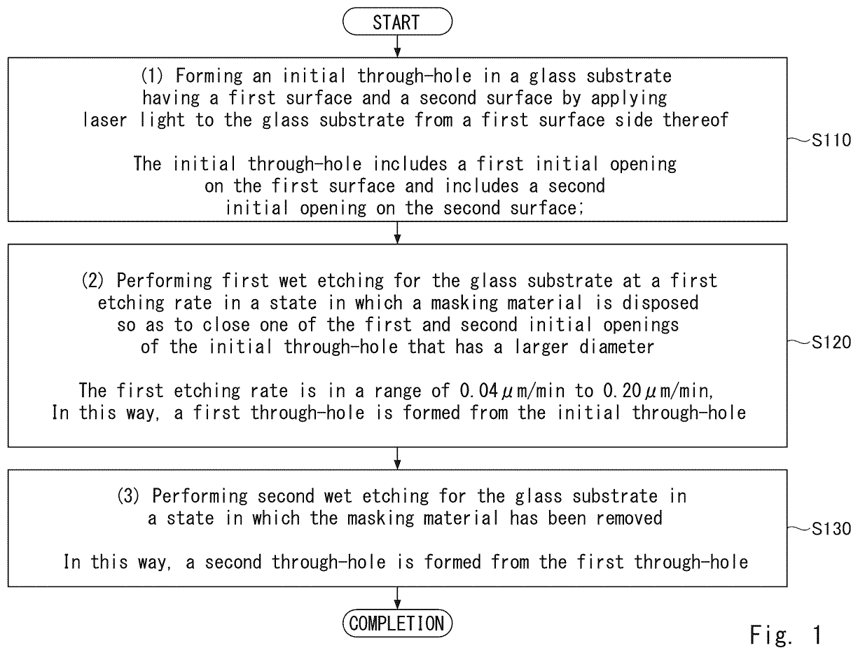

FIG. 1 schematically shows a flow of a method for manufacturing a glass substrate with a through-hole according to an embodiment of the present invention.

As shown in FIG. 1, the method for manufacturing a glass substrate with a through-hole according to an embodiment of the present invention (hereinafter referred to as a “first method”) comprises: (1) a step (S110) of forming an initial through-hole in a glass substrate having a first surface and a second surface by applying laser light to the glass substrate from a first surface side thereof, the initial through-hole including a first initial opening on the first surface and including a second initial opening on the second surface; (2) a step (S120) of performing first wet etching for the glass substrate at a first etching rate in a state in which a masking material is disposed so as to close one of the first and second initial openings of the initial through-hole that has a larger diameter, and thereby forming a first through-hole from the initial through-hole, the first etching rate being in a range of 0.04 μm/min to 0.20 μm/min; and (3) a step (S130) of performing second wet etching for the glass substrate in a state in which the masking material has been removed, and thereby forming a second through-hole from the first through-hole.

Each of the steps will be described hereinafter.

### (Step S110)

Firstly, a glass substrate having first and second surfaces opposite to each other is prepared.

The composition of the glass substrate is not limited to any particular compositions. For example, the glass substrate may be formed of soda lime glass or alkaline-free glass. The thickness of the glass substrate is not limited to any particular values. For example, the glass substrate may have a thickness of 0.05 mm to 1.2 mm.

Next, laser light is applied to the glass substrate from the first surface side thereof, and an initial through-hole is thereby formed in the glass substrate.

The laser light to be applied is not limited to any particular laser light as long as the initial through-hole can be formed in the glass substrate by the laser light. For example, the laser light may be a CO₂ laser.

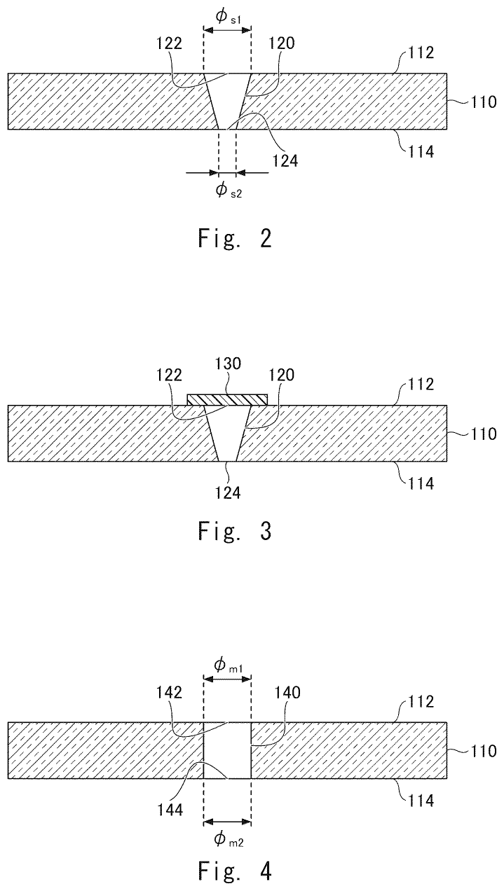

FIG. 2 schematically shows a cross section of a glass substrate in which an initial through-hole has been formed.

As shown in FIG. 2, a glass substrate 110 has a first surface 112 and a second surface 114 opposite to each other. The first surface 112 is the surface which has been irradiated with the laser.

An initial through-hole 120 extending from the first surface 112 to the second surface 114 is formed in the glass substrate 110.

Note that in the example shown in FIG. 2, only one initial through-hole 120 is shown. However, the number of initial through-holes 120 is not limited to any particular number. For example, when the glass substrate 110 is used in applications such as a glass interposer, a large number of initial through-holes 120, e.g., more than 10,000 initial through-holes, may be formed in the glass substrate 110.

The initial through-hole 120 includes a first initial opening 122 on the first surface 112 and includes a second initial opening 124 on the second surface 114.

The diameter φₛ₁ of the first initial opening 122 may be larger than the diameter φₛ₂ of the second initial opening 124, so that a relation φₛ₁>φₛ₂ may hold. Alternatively, the diameter ₛ₁ of the first initial opening 122 may be smaller than the diameter φₛ₂ of the second initial opening 124, so that a relation φₛ₁<φₛ₂ may hold.

In the case of φₛ₁>φₛ₂, the diameter φₛ₁ of the first initial opening 122 may be, but not limited to, in the range of, for example, 20 μm to 200 μm. Further, the diameter φₛ₂ of the second initial opening 124 may be, but not limited to, in the range of, for example, 10 μm to 150 μm.

Note that a step of annealing the glass substrate 110 may be performed after the step S110 and before the next step S120.

By annealing the glass substrate 110, the stress accumulated inside the glass substrate 110 by the laser light processing can be alleviated. In this way, the risk of the occurrence of cracks in the glass substrate 110 in the subsequent steps can be reduced.

The annealing process is typically performed in the atmosphere. The temperature of the annealing process is not limited to any particular temperatures, but is, for example, in the range of 300 °C to 1500 °C.

### (Step S120)

Next, a masking material is disposed in one of the first and second initial openings 122 and 124 of the initial through-hole 120 that has a larger diameter.

Here, as an example, it is assumed that φₛ₁>φₛ₂, and a case where a masking material 130 is disposed in the first initial opening 122 will be described.

FIG. 3 schematically shows a cross section of the glass substrate 110 in which the masking material 130 is disposed on the side thereof on which the first surface 112 is located.

As shown in FIG. 3, the masking material 130 is disposed so as to close the first initial opening 122.

The form of the masking material 130 is not limited to any particular forms. For example, the masking material 130 may be a film. Further, the material of the masking material 130 is not limited to any particular materials. For example, the masking material 130 may be formed of a resin film or a metal film. Further, the thickness of the masking material 130 is not limited to any particular values, and a masking material 130 having an ordinary thickness may be used.

Note that in the example shown in FIG. 3, the masking material 130 is disposed so as to mask only the first initial opening 122 (and its periphery). However, this is merely an example, and how to dispose the masking material 130 is not limited to any particular ways as long as the first initial opening 122 can be closed by the masking material 130. For example, the masking material 130 may be disposed over the entire first surface 112.

Next, in this state, first wet etching is performed for the glass substrate 110. As a result, a first through-hole is formed from the initial through-hole 120.

The etchant used in the first wet etching is not limited to any particular etchants as long as the glass substrate 110 can be properly etched.

For example, a hydrofluoric acid-based solution may be used as the etchant.

Further, conditions such as the etching temperature and the etching time are not limited to any particular conditions, and ordinary conditions for wet etching of glass may be selected.

By performing the first wet etching in such a manner, in the initial through-hole 120, a larger etching amount can be achieved on the side of the glass substrate on which the second initial opening 124 is located than on the side thereof on which the first initial opening 122 is located.

As a result, the obtained first through-hole has a form in which the “tapered shape” is significantly alleviated and the “non-straight part” such as a narrowed part and/or a bulge is reduced.

After that, the masking material 130 is removed.

FIG. 4 schematically shows a cross section of the glass substrate 110 after the first wet etching is performed. FIG. 4 shows a cross section of the glass substrate 110 after the masking material 130 is removed.

As shown in FIG. 4, the first through-hole 140 includes a first opening 142 on the side of the glass substrate on which the first surface 112 is located and includes a second opening 144 on the side thereof on which the second surface 114 is located. The first opening 142 has a diameter φₘ₁ and the second opening 144 has a diameter φₘ₂.

As described above, in the first wet etching, the etching rate is adjusted to the range of 0.04 μm/min to 0.20 μm/min.

Here, it should be noted that the difference between the diameters of the openings on both sides, i.e., the absolute value of φₘ₁−φₘ₂, is significantly smaller than the difference between the diameters of the openings on both sides in the initial through-hole 120, i.e., the absolute value of φₛ₁-φₛ₂.

Note that, strictly speaking, when the first wet etching is performed in the state in which the masking material 130 is disposed as shown in FIG. 3, the first and second surfaces 112 and 114 of the glass substrate 110 are also etched. Therefore, in the obtained glass substrate 100, the surfaces on both sides opposite to each other are newly-generated surfaces different from the original first and second surfaces 112 and 114 before the first wet etching is performed.

However, in the present application, in order to avoid complicating the explanation, the surfaces on both sides opposite to each other in the glass substrate 110 after the first wet etching is performed are referred to as the “first surface” 112 and the “second surface” 114 without changing their names. The same applies to the second and subsequent etching processes.

Meanwhile, if the first wet etching is performed by disposing the masking material 130 over the entire first surface 112 of the glass substrate 110, the first surface 112 is unchanged.

### (Step S130)

Next, second wet etching is performed for the glass substrate 110. As a result, a second through-hole is formed from the first through-hole 140.

The second wet etching is performed in order to shape the finally obtained through-hole (i.e., the second through-hole).

The etchant used in the second wet etching is not limited to any particular etchants as long as the glass substrate 110 can be properly etched.

The etchant used in the second wet etching may be the same as or different from the etchant used in the above-described first wet etching.

Further, in the second wet etching, conditions such as the etching temperature and the etching time are not limited to any particular conditions, and ordinary conditions for wet etching of glass may be selected.

The etching rate of the second wet etching is, for example, in the range of 0.01 μm/min to 5 μm/min.

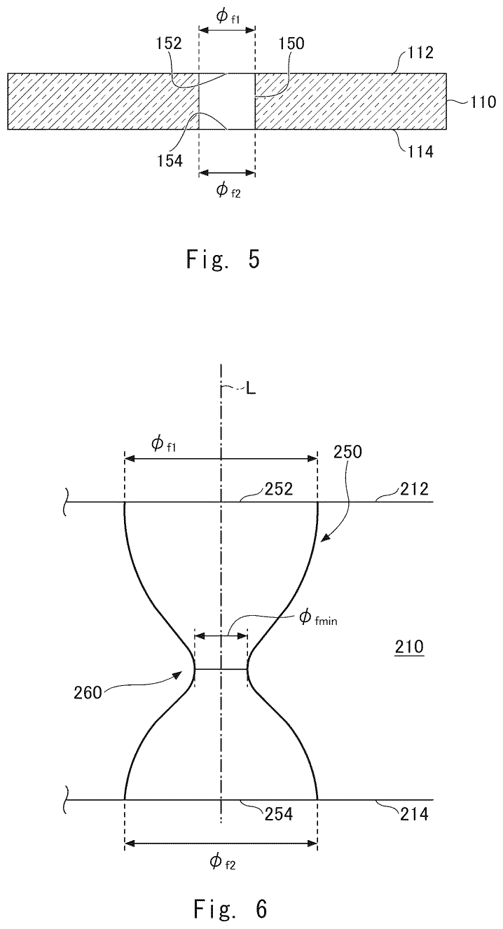

FIG. 5 schematically shows a cross section of the glass substrate 110 after the second wet etching is performed.

As shown in FIG. 5, the second through-hole 150 has a first processed opening 152 on the side of the glass substrate on which the first surface 112 is located and a second processed opening 154 on the side thereof on which the second surface 114 is located. The first processed opening 152 has a diameter φ_{f1} and the second processed opening 154 has a diameter (Pf.

A glass substrate with a through-hole can be manufactured through the above-described series of steps.

In the first method described above, the “tapered shape” is alleviated and the “non-straight part” is also reduced by the step S120. As a result, a first through-hole 140 having a shape closer to a cylindrical shape can be obtained. Therefore, even after the second wet etching for uniformly widening the shape of the first through-hole 140 is performed in the subsequent step S130, the shape closer to a cylindrical shape can be maintained in the second through-hole 150.

As a result of the above-described effects, it is possible to form a second through-hole 150 having a shape closer to a desired shape in an embodiment according to the present invention.

(Regarding Feature of Shape of Through Hole Obtained in Method for Manufacturing Glass Substrate with Through Hole According to Embodiment of Invention)

Next, features of the shape of a through-hole (e.g., corresponding to the second through-hole 150 shown in FIG. 5) obtained by a method for manufacturing a glass substrate with a through-hole according to an embodiment of the present invention will be described in a more detailed manner with reference to FIGS. 6 to 8.

FIG. 6 schematically shows an enlarged view of a cross section of a through-hole (hereinafter referred to as a “processed through-hole”) obtained by a method for manufacturing a glass substrate with a through-hole according to an embodiment of the present invention along an extension axis thereof.

Note that in FIG. 6, the shape of the processed through-hole is shown in an exaggerated manner in order to clarify the following explanation. It should be noted that the shape of an actually-obtained processed through-hole is closer to a “cylindrical” shape.

As shown in FIG. 6, the processed through-hole 250 has a first processed opening 252 on the side of the glass substrate 210 on which the first surface 212 is located and a second processed opening 254 on the side of the glass substrate 210 on which the second surface 214 is located. The first processed opening 252 has a diameter φ_{f1} and the second processed opening 254 has a diameter φ_{f2}.

Further, the processed through-hole 250 includes a constricted part 260.

Note that the constricted part 260 means a position (surface) in the processed through-hole 250 at which the size of the cross section thereof perpendicular to the extension axis L is the minimum. The constricted part 260 has a diameter φ_{fmin}.

In an embodiment according to the present invention, the absolute value Δφ of the difference between the diameter φ_{f1} of the first processed opening 252 and the diameter φ_{f2} of the second processed opening 254 in the processed through-hole 250 may be 5 μm or smaller. In particular, Δφ is preferably 3.5 μm or smaller, or 3 μm or smaller, and more preferably 1 μm or smaller.

In an embodiment according to the present invention, as in the above-described first method, first wet etching is performed in a state in which a masking material is disposed in one of the initial openings that has a larger diameter. Therefore, it is possible to reduce the difference between the diameters of the first and second initial openings. Consequently, it is possible to reduce Δφ to 5 μm or smaller even in the processed through-hole 250 that is obtained after the second wet etching.

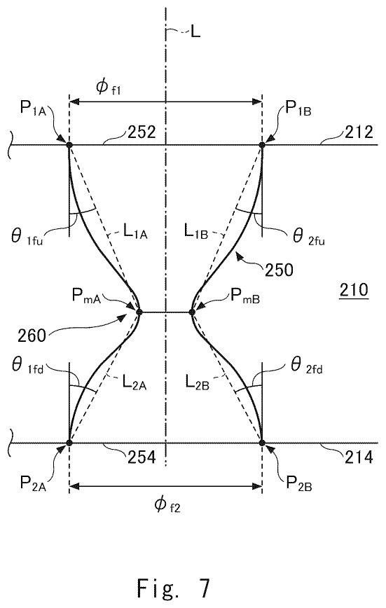

Next, FIG. 7 schematically shows an enlarged view of a cross section of the processed through-hole 250 along the extension axis L thereof similar to that shown in FIG. 6. In FIG. 7, the shape of the processed through-hole 250 is also shown in an exaggerated manner.

In an embodiment according to the present invention, the processed through-hole 250 has a feature that the “taper angle θₐᵥₑ” is significantly reduced.

Note that the taper angle θₐᵥₑ is defined as described below.

As shown in FIG. 7, one of ends of the first processed opening 252 is referred to as a first end P_{1A}, and the other end thereof is referred to as a second end P_{1B}. Similarly, in the second processed opening 254, an end on the same side as the first end P_{1A} is referred to as a third end P_{2A}, and an end on the same side as the second end P_{1B} is referred to as a fourth end P_{2B}. Further, in the constricted part 260, an end on the same side as the first end P_{1A} is referred to as a fifth end P_{mA}, and an end on the same side as the second end P_{1B} is referred to as a sixth end P_{mB}.

Next, a line segment obtained by connecting the first end P_{1A} and the fifth end P_{mA} by a straight line is referred to as a line segment L_{1A}, and a line segment obtained by connecting the second end P_{1B} and the sixth end P_{mB} by a straight line is referred to as a line segment L_{1B}. Further, a line segment obtained by connecting the third end P_{2A} and the fifth end P_{mA} by a straight line is referred to as a line segment L_{2A}, and a line segment obtained by connecting the fourth end P_{2B} and the sixth end P_{mB} by a straight line is referred to as a line segment L_{2B}.

Next, a perpendicular line is drawn from the first end P_{1A} toward the inside of the glass substrate 210, and an angle formed between this perpendicular line and the line segment L_{1A} is referred to as a first upper taper angle θ_{1fu}. Similarly, a perpendicular line is drawn from the second end P_{1B} toward the inside of the glass substrate 210, and an angle formed between this perpendicular line and the line segment L_{1B} is referred to as a second upper taper angle θ_{2fu}.

Similarly, a perpendicular line is drawn from the third end P_{2A} toward the inside of the glass substrate 210, and an angle formed between this perpendicular line and the line segment L_{2A} is referred to as a first lower taper angle θ_{1fd}. Similarly, a perpendicular line is drawn from the fourth end P_{2B} toward the inside of the glass substrate 210, and an angle formed between this perpendicular line and the line segment L_{2B} is referred to as a second lower taper angle θ_{2fu}.

The average of the four angles, i.e., the first upper taper angle θ_{1fu}, the second upper taper angle θ_{2fu}, the first lower taper angle θ_{1fd}, and the second lower taper angle θ_{2fd}, is defined as a taper angle θₐᵥₑ.

In an embodiment according to the present invention, the taper angle θₐᵥₑ is, for example, smaller than 4°. The taper angle θₐᵥₑ is preferably smaller than 3.5°, and more preferably smaller than 3.0°.

Note that depending on the cross-sectional shape of the processed through-hole 250, the diameter φ_{f1} of the first processed opening 252 or the diameter φ_{f2} of the second processed opening 254 may correspond to a position where the size of the cross section of the through-hole perpendicular to the extension axis L is the minimum. In this case, the constricted part 260 coincides with the first processed opening 252 or the second processed opening 254.

In such a case, in the above-described method for determining the taper angle θₐᵥₑ, a line segment connecting the first end P_{1A} and the third end P_{2A} may be referred to as a line segment L₁′, and a line segment connecting the second end P_{1B} and the fourth end P_{2B} may be referred to as a line segment L₂′.

That is, when the constricted part 260 coincides with the second processed opening 254, the taper angle θₐᵥₑ is determined by averaging the first upper taper angle θ_{1fu} obtained from the line segment L₁′ and the perpendicular line drawn from the first end P_{1A} and the second upper taper angle θ_{2fu} obtained from the line segment L₂′ and the perpendicular line drawn from the second end P_{1B}.

Similarly, when the constricted part 260 coincides with the first processed opening 252, the taper angle θₐᵥₑ is determined by averaging the first lower taper angle θ_{1fd} obtained from the line segment L₁′ and the perpendicular line drawn from the third end P_{2A} and the second lower taper angle θ_{2fc} obtained from the line segment L₂′ and the perpendicular line drawn from the fourth end P_{2B}.

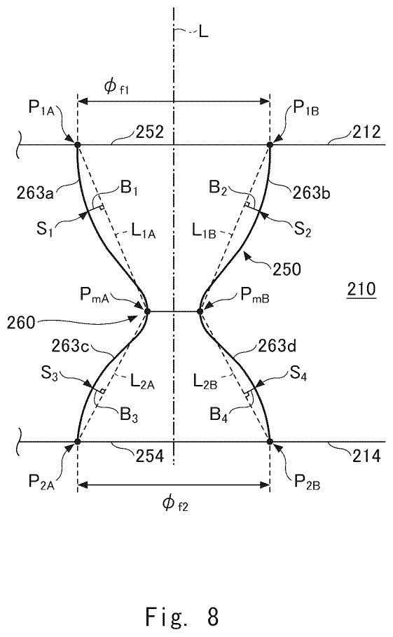

Next, FIG. 8 schematically shows an enlarged view of a cross section of the processed through-hole 250 along the extension axis L similar to that shown in FIG. 6. In FIG. 8, the shape of the processed through-hole 250 is also shown in an exaggerated manner.

In an embodiment according to the present invention, the processed through-hole 250 has a feature that the “bulge Bₘₐₓ” is significantly suppressed.

Note that the bulge Bₘₐₓ is defined as described below.

Similarly to the case where the taper angle θₐᵥₑ is determined, a first end P_{1A}, a second end P_{1B}, a third end P_{2A}, a fourth end P_{2B}, a fifth end P_{mA}, and a sixth end P_{mB} are defined.

Further, similarly to the case where the taper angle θₐᵥₑ is determined, a line segment L_{1A}, a line segment L_{1B}, a line segment L_{2A}, and a line segment L_{2B} are obtained.

Further, in the processed through-hole 250, the sidewall part between the first end P_{1A} and the fifth end P_{mA} is referred to as a first sidewall 263a, and the sidewall part between the second end P_{1B} and the sixth end P_{mB} is referred to as a second sidewall 263b. Similarly, in the processed through-hole 250, the sidewall part between the third end P_{2A} and the fifth end P_{mA} is referred to as a third sidewall 263c, and the sidewall part between the fourth end P_{2B} and the sixth end P_{mB} is referred to as a fourth sidewall 263d.

The maximum value of the distance between the first sidewall 263a and the line segment L_{1A} is defined as a bulge B₁ (position S₁). Further, the maximum value of the distance between the second sidewall 263b and the line segment L_{1B} is defined as a bulge B₂ (position S₂). Similarly, the maximum value of the distance between the third sidewall 263c and the line segment L_{2A} is defined as a bulge B₃ (position S₃). Further, the maximum value of the distance between the fourth sidewall 263d and the line segment L_{2B} is defined as a bulge B₄ (position S₄).

The maximum value among the four bulges B₁ to B₄ is defined as a bulge Bₘₐₓ.

In an embodiment according to the present invention, the bulge Bₘₐₓ defined as described above is, for example, 5 μm or smaller. The bulge Bₘₐₓ is preferably 4 μm or smaller.

Note that as described above, when the constricted part 260 coincides with the first processed opening 252 or the second processed opening 254, the bulge Bₘₐₓ is evaluated by a method similar to the method that is used in the case of the taper angle θₐᵥₑ.

That is, one bulge B in the processed through-hole 250 is determined from the maximum distance between the line segment L₁′ drawn as described above and the sidewall on the side corresponding to the line segment L₁′. Further, another bulge B is determined from the maximum distance between the line segment L₂′ and the sidewall corresponding to the line segment L₂′. The larger one of the two obtained values is defined as the bulge Bₘₐₓ of the processed through-hole 250.

(Glass Substrate with Through-Hole According to Embodiment of Present Invention)

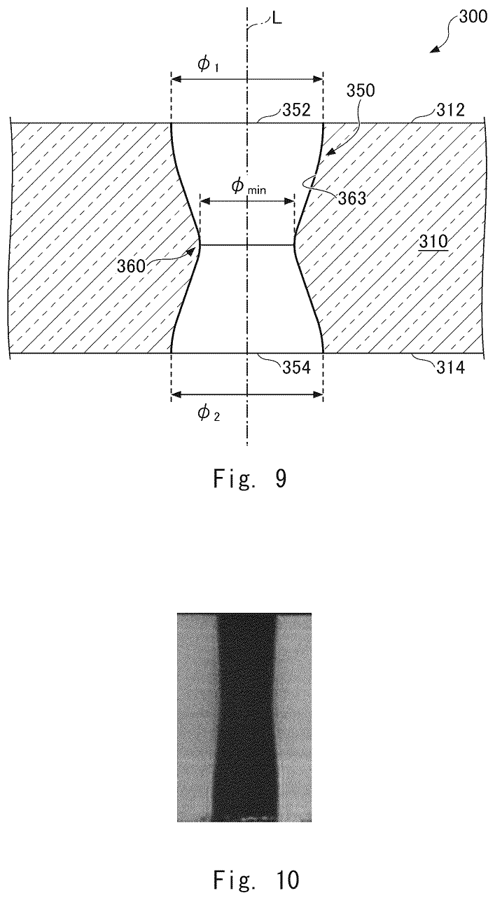

Next, a glass substrate with a through-hole according to an embodiment of the present invention will be described with reference to FIG. 9.

FIG. 9 schematically shows an example of a cross section of a glass substrate with a through-hole according to an embodiment of the present invention. It should be noted that the form of the through-hole is shown in an exaggerated manner in FIG. 9.

As shown in FIG. 9, the glass substrate with a through-hole (hereinafter referred to as a “first substrate”) 300 according to an embodiment of the present invention includes a glass substrate 310 having a first surface 312 and a second surface 314 opposite to each other.

The glass substrate 310 has, for example, a thickness in the range of 0.05 mm to 1.2 mm.

Further, the first substrate 300 also includes at least one through-hole 350 extending from the first surface 312 to the second surface 314.

Note that in the example shown in FIG. 9, the first substrate 300 includes only one through-hole 350. However, the number of through-holes 350 is not limited to any particular numbers. For example, when the first substrate 300 is used in applications such as a glass interposer, a large number of through-holes 350, e.g., more than 10,000 initial through-holes, may be formed in the first substrate 300.

Each through-hole 350 includes a first opening 352 on the first surface 312 and includes a second opening 354 on the second surface 314. Further, the through-hole 350 may include a constricted part 360.

The diameter of the first opening 352 is represented by φ₁; the diameter of the second opening 354 is represented by φ₂; and the diameter of the constricted part 360 is represented by φₘᵢₙ.

Note that in the first substrate 300, the “tapered shape” of the through-hole 350 is significantly alleviated, and the “non-straight part” is also significantly reduced.

Specifically, in the first substrate 300, each through-hole 350 has the following features:
(i) Δφ (absolute value) is 5 μm or smaller;
(ii) The taper angle θₐᵥₑ is 4° or smaller; and
(iii) The bulge Bₘₐₓ is, for example, 5 μm or smaller.

Note that Δφ (absolute value), the taper angle θₐᵥₑ, and the bulge Bₘₐₓ are defined as described above with reference to FIGS. 6 to 8.

In particular, Δφ (absolute value) is preferably 3.5 μm or smaller, or 3 μm or smaller, and more preferably 1 m or smaller. Further, the taper angle θₐᵥₑ is preferably smaller than 3.50, and more preferably smaller than 3.0° further, the bulge Bₘₐₓ is preferably smaller than 4 μm, and more preferably smaller than 3 μm.

Since the through-hole 350 has such a shape, the through-hole 350 can be properly filled with a conductive material in the first substrate 300. Further, when the first substrate 300, in which the through-hole 350 is filled with the conductive material, is used and an electric current is fed thereto, the occurrence of an energy loss can be significantly prevented.

Further, the first substrate 300 has a feature that the surface roughness (the maximum height Rz. The same applies hereinafter) of the sidewall 363 of the through-hole 350 changes along the extension axis L of the through-hole 350.

Specifically, when the distance from the first opening 352 of the through-hole 350 in the depth direction is represented by x (μm), and the surface roughness (maximum height Rz) of the sidewall 363 of the through-hole 350 is represented by Q (μm), the relationship between Q and x can be approximated by

Q=mx+b Formula (1).

In Formula (1), in is an inclination in
(a) a range of −0.001 to −0.005, or
(b) a range of 0.001 to 0.005.

Owing to the above-described feature, it is possible to dispose a conductive material inside the through-hole 350 more uniformly in the first substrate 300. That is, in general, a conductive material tends to adhere more easily to the sidewall of a through-hole having large surface roughness than to the sidewall of a through-hole having small surface roughness. Therefore, when a conductive material is disposed inside the through-hole 350, it is possible to, by feeding the conductive material from the opening corresponding to the smaller surface roughness of the sidewall 363, dispose the conductive material sufficiently up to the opening on the opposite side corresponding to the larger surface roughness of the sidewall 363.

Note that a first substrate 300 having the above-described feature can be manufactured by a method according to an embodiment of the present invention such as the above-described first method.

That is, in the method according to an embodiment of the present invention, a masking material is disposed in the larger opening of the initial through-hole in the first etching process. Therefore, on the side of the glass substrate on which the small opening is located and the masking material is not disposed, the etching by the etching solution becomes more effective, so that the sidewall is etched by a larger etching amount.

As a result, on the side of the glass substrate on which the small opening of the initial through-hole is located, the surface of the sidewall becomes smoother than that on the side of the glass substrate on which the large opening is located, so that a surface roughness (maximum height Rz) that is “inclined” in the depth direction is obtained in the through-hole.

### EXAMPLES

Examples according to the present invention will be described hereinafter. Note that in the following description, Examples 1 to 3 are examples according to the present disclosure, and Example 21 to 23 are comparative examples.

### Example 1

A glass substrate with a through-hole was manufactured by a method described below.

Firstly, a glass substrate having a first surface and a second surface opposite to each other was prepared.

An alkali-free glass having a length of 50 mm, a width of 50 mm, and a thickness of 0.23 mm was used for the glass substrate.

Next, three initial through-holes were formed by irradiating the first surface of this glass substrate with laser light.

A CO₂ laser having a wavelength of 10.6 μm was used as the laser light, and its output was 100 W.

Each of the obtained initial through-holes included a first initial opening on the first surface of the glass substrate and included a second initial opening on the second surface thereof. The diameter of the first initial opening was larger than that of the second initial opening.

After that, an annealing process was performed for the glass substrate in the atmosphere.

Next, a masking material was disposed so as to close the first initial opening of each initial through-hole. Specifically, the masking material was disposed over the entire surface of the first surface of the glass substrate. A resin film (331B-N; manufactured by 3M) was used as the masking material.

Next, a first etching process was performed for the glass substrate.

In the first etching process, a hydrofluoric acid-based solution was used as the etching solution. The etching rate was 0.073 μm/min. As a result, the initial through-hole (i.e., each initial through-hole) changed into a first through-hole.

The obtained first through-hole (i.e., each first through-hole) included a first opening on the first surface of the glass substrate and included a second opening on the second surface thereof. The diameter of the first opening was larger than that of the second opening.

Next, the masking material was removed from the glass substrate, and a second etching process was performed.

In the second etching process, an alkaline solution was used as the etching solution. The etching rate was 0.07 μm/min. As a result, the first through-hole (i.e., each first through-hole) changed into a second through-hole.

The obtained second through-hole (i.e., each second through-hole) included a first processed opening on the first surface of the glass substrate and included a second processed opening on the second surface thereof.

A glass substrate with a through-hole (hereinafter referred to as “Sample 1”) was obtained through the above-described series of steps.

### Example 2

A glass substrate with a through-hole was manufactured by a method similar to that in Example 1.

However, in Example 2, the concentration of the etching solution in the first etching process was changed, and the etching rate was set to 0.12 m/min.

The obtained glass substrate with a through-hole is referred to as “Sample 2”.

### Example 3

A glass substrate with a through-hole was manufactured by a method similar to that in Example 1.

However, in Example 3, the concentration of the etching solution in the first etching process was changed, and the etching rate was set to 0.18 m/min.

The obtained glass substrate with a through-hole is referred to as “Sample 3”.

### Example 21

A glass substrate with a through-hole was manufactured by a method similar to that in Example 1.

However, in Example 21, the concentration of the etching solution in the first etching process was changed, and the etching rate was set to 0.03 μm/min.

The obtained glass substrate with a through-hole is referred to as “Sample 21”.

### Example 22

A glass substrate with a through-hole was manufactured by a method similar to that in Example 1.

However, in Example 22, the concentration of the etching solution in the first etching process was changed, and the etching rate was set to 0.31 m/min.

The obtained glass substrate with a through-hole is referred to as “Sample 22”.

### Example 23

A glass substrate with a through-hole was manufactured by a method similar to that in Example 1.

However, in Example 23, only the second etching process was performed.

The obtained glass substrate with a through-hole is referred to as “Sample 23”.

### Evaluation

Evaluations described below were made by using the glass substrates formed in the respective examples described above.

### (Measurement of Shape of Through-Hole)

In each example, the shape of the first through-hole after the first etching process and that of the second through-hole after the second etching process were evaluated.

Specifically, a cross section along the extension axis was adjusted in each of (three) first through-holes and (three) second through-holes. Further, the cross sections of the obtained through-holes were observed by an optical microscope, and their various sizes were measured.

Each of the sizes shown below is a value obtained by averaging measured values obtained in the three through-holes.

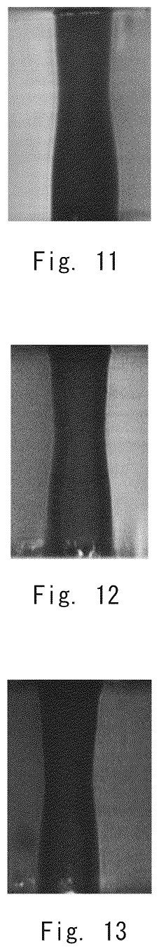

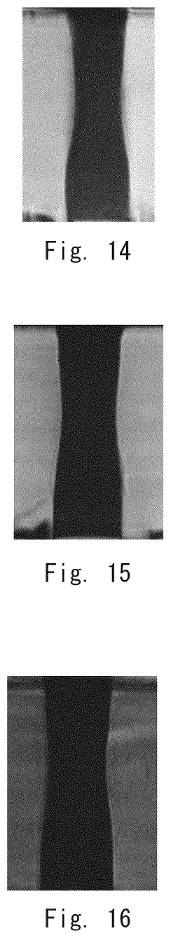

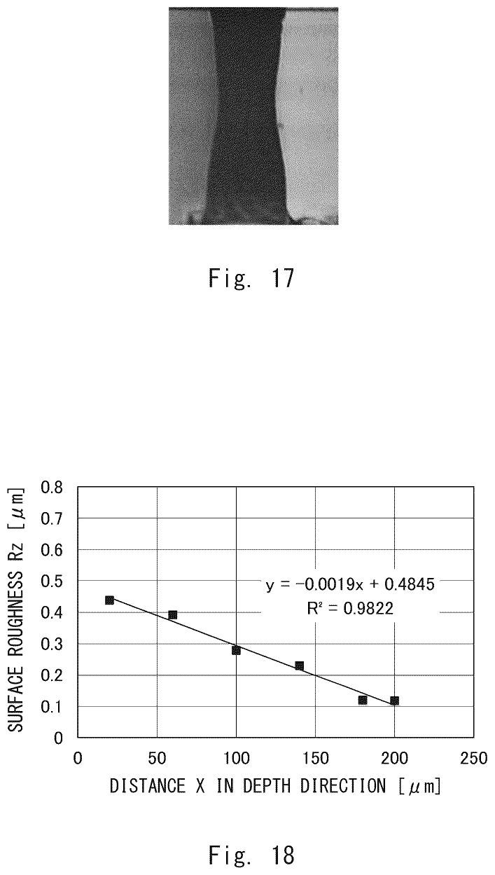

FIGS. 10 to 14 show examples of cross-sectional forms of the first through-holes in Examples 1 to 3 and Examples 21 and 22, respectively. Further, FIGS. 15 to 17 show examples of cross-sectional forms of the second through-holes in Examples 1, 2 and 22, respectively.

In Table 1 shown below, results of measurements of sizes of the first through-holes formed in the respective examples are summarized.

TABLE 1

| | Etching rate | Diameter of first | Diameter of second | ΔΦ | Taper angle | Bulge Bₘₐₓ |
|---|---|---|---|---|---|---|
| Example | (μm/min) | opening (μm) | opening (μm) | (μm) | θₐᵥₑ (°) | (μm) |
| 1 | 0.07 | 71.6 | 68.5 | 3.1 | 3.55 | 2.9 |
| 2 | 0.07 | 71.4 | 70.8 | 0.6 | 3.74 | 3.6 |
| 3 | — | — | — | — | — | — |
| 21 | — | — | — | — | — | — |
| 22 | 0.07 | 71.7 | 70.8 | 0.9 | 4.9 | 5.92 |

Further, in Table 2 shown below, results of measurements of sizes of the second through-holes formed in the respective examples are summarized.

TABLE 2

| | | Diameter of first | Diameter of second | | | |
|---|---|---|---|---|---|---|
| | Etching rate | processed opening | processed opening | ΔΦ | Taper angle | Bulge Bₘₐₓ |
| Example | (μm/min) | (μm) | (μm) | (μm) | θₐᵥₑ (°) | (μm) |
| 1 | 0.07 | 71.6 | 68.5 | 3.1 | 3.55 | 2.9 |
| 2 | 0.07 | 71.4 | 70.8 | 0.6 | 3.74 | 3.6 |
| 3 | — | — | — | — | — | — |
| 21 | — | — | — | — | — | — |
| 22 | 0.07 | 71.7 | 70.8 | 0.9 | 4.9 | 5.92 |

In Example 22, the taper angle θₐᵥₑ of the second through-hole was 4.9°, and the bulge Bₘₐₓ was 5.9 μm. Therefore, it can be seen that in Sample 22, the second through-hole had a relatively large tapered shape and the non-straight part is outstanding.

In contrast, in Examples 1 to 2, it has been found that: Δφ of the second through-hole was 3.1 μm or smaller; the taper angle θₐᵥₑ was 3.8° or smaller; and the bulge Bₘₐₓ was suppressed to 3.6 μm or smaller.

Therefore, it can be said that in Samples 1 and 2, the second through-hole had a form close to a straight shape in which the tapered shape is alleviated.

### (Measurement of Surface Roughness of Sidewall of Through-Hole)

The surface roughness (maximum height Rz) of the sidewall of the second through-hole was measured by using Samples 1 and 23.

A laser microscope (VK-X1000; manufactured by Keyence Corporation) was used for the measurement.

Specifically, in the second through-hole, the surface roughness of the sidewall was measured at each of positions of 20 μm, 60 μm, 100 μm, 140 μm, 180 μm, and 200 μm from the first processed opening in the depth direction. At each position, the measurement area was a range of 5 m along the horizontal direction of the sidewall.

Further, the average value of the maximum height Rz at each depth position was determined by averaging results obtained in the three second through-holes.

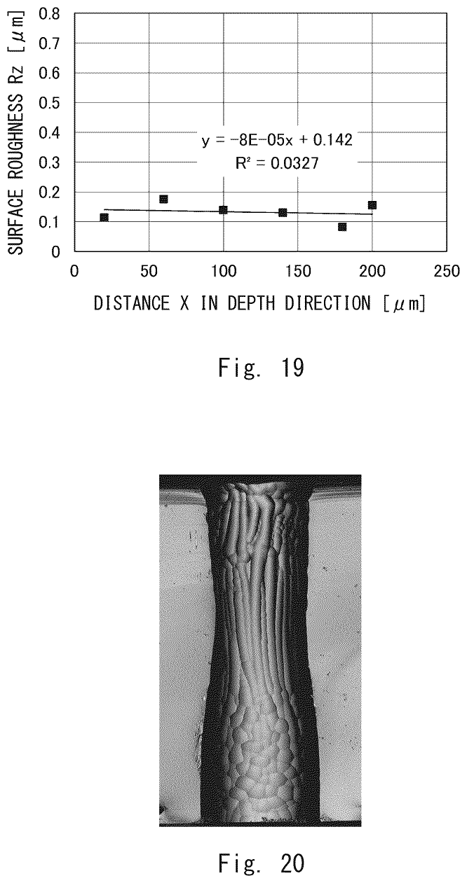

FIG. 18 shows a relationship between the depth position and the surface roughness obtained in Sample 1. Further, FIG. 19 shows a relationship between the depth position and the surface roughness obtained in Sample 23.

From FIG. 19, it can be seen that in Sample 23, there is no recognizable difference in the surface roughness depending on the depth direction of the second through-hole.

In contrast to this, from FIG. 18, it can be seen that in Sample 1, the surface roughness linearly changes along the depth direction of the second through-hole.

In FIG. 18, when the distance in the depth direction is represented by x (μm) and the surface roughness of the inner wall is represented by Q (μm), from the plot in the graph, the relationship between Q and x is approximated by

Q=mx+b Formula (1).

Further, the inclination m was −0.0019.

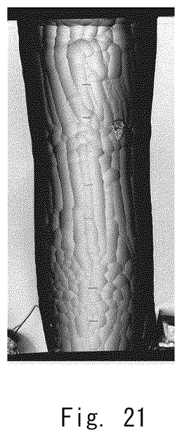

FIGS. 20 and 21 show examples of photographs of cross-sections of the second through-holes in Samples 1 and 23, respectively, taken by a laser microscope.

As shown in the photographs, it has been found that in an embodiment according to the present invention, the second through-hole has such a feature that the surface roughness changes along the depth direction.

### Embodiments of Present Invention

The present invention includes embodiments shown below.

### Embodiment 1

A method for manufacturing a glass substrate with a through-hole, comprising:
(1) a step of forming an initial through-hole in a glass substrate having a first surface and a second surface by applying laser light to the glass substrate from a first surface side thereof, the initial through-hole including a first initial opening on the first surface and including a second initial opening on the second surface;
(2) a step of performing first wet etching for the glass substrate at a first etching rate in a state in which a masking material is disposed so as to close one of the first and second initial openings of the initial through-hole that has a larger diameter, and thereby forming a first through-hole from the initial through-hole, the first etching rate being in a range of 0.04 μm/min to 0.20 μm/min; and
(3) a step of performing second wet etching for the glass substrate in a state in which the masking material has been removed, and thereby forming a second through-hole from the first through-hole.

### Embodiment 2

The method described in Embodiment 1, wherein the laser light is a CO₂ laser light.

### Embodiment 3

The method described in Embodiment 1 or 2, further comprising a step (4) of annealing the glass substrate between the step (1) and the step (2).

### Embodiment 4

The method described in any one of Embodiments 1 to 3, wherein an etching rate in the second wet etching is between 0.07 μm/min and 2 μm/min.

### Embodiment 5

The method described in any one of Embodiments 1 to 4, wherein an etchant used in the first wet etching is the same as or different from that used in the second wet etching.

### Embodiment 6

The method described in any one of Embodiments 1 to 5, wherein
the second through-hole includes a first processed opening on the first surface of the glass substrate and includes a second processed opening on the second surface of the glass substrate, and
a difference Δφ (absolute value) between a diameter φ_{f1} of the first processed opening and a diameter φ_{f2} of the second processed opening is 5 μm or smaller.

### Embodiment 7

The method described in any one of Embodiments 1 to 6, wherein
in the second through-hole, a position at which a size of a cross section perpendicular to an extension axis of the second through-hole is a minimum is referred to as a constricted part,
in cross section of the second through-hole along the extension axis thereof,
when one of ends of the first processed opening is referred to as a first end P_{1A}; the other end is referred to as a second end P_{1B}; an end of the second processed opening on the same side as the first end P_{1A} is referred to as a third end P₂ₘ; an end of the second processed opening on the same side as the second end P_{1B} is referred to as a fourth end P_{2B}; an end of the constricted part on the same side as the first end P_{1A} is referred to as a fifth end P_{mA}; and an end of the constricted part on the same side as the second end P_{1B} is referred to as a sixth end P_{mB},
a line segment connecting the first end P_{1A} and the fifth end P_{mA} is referred to as a line segment L_{1A}; a line segment connecting the second end P_{1B} and the sixth end P_{mB} is referred to as a line segment L_{1B}; a line segment connecting the third end P_{2A} and the fifth end P_{mA} is referred to as a line segment L_{2A}; and a line segment connecting the fourth end P_{2B} and the sixth end P_{mB} is referred to as a line segment L_{2B},
a perpendicular line is drawn from the first end P_{1A} toward inside of the glass substrate, and an angle formed between this perpendicular line and the line segment L_{1A} is referred to as a first upper taper angle θ_{1fu};
a perpendicular line is drawn from the second end P_{1B} toward inside of the glass substrate, and an angle formed between this perpendicular line and the line segment Lin is referred to as a second upper taper angle θ_{2fu};
a perpendicular line is drawn from the third end P_{2A} toward inside of the glass substrate, and an angle formed between this perpendicular line and the line segment L_{2A} is referred to as a first lower taper angle θ_{1fd};
a perpendicular line is drawn from the fourth end P_{2B} toward inside of the glass substrate, and an angle formed between this perpendicular line and the line segment L_{2B} is referred to as a second upper taper angle θ_{2fd}, and
an average of θ_{1fu}, θ_{2fu}, θ_{1fd}, and θ_{2fd} is referred to as a taper angle θₐᵥₑ,
this taper angle θₐᵥₑ is smaller than 4°.

### Embodiment 8

The method described in Embodiment 7, wherein
in the cross section along the extension axis of the second through-hole,
when a sidewall part between the first end P_{1A} and the fifth end P_{mA} is referred to as a first sidewall; a sidewall part between the second end P_{1B} and the sixth end P_{mB} is referred to as a second sidewall; a sidewall part between the third end P_{2A} and the fifth end P_{mA} is referred to as a third sidewall; and a sidewall part between the fourth end P_{2B} and the sixth end P_{mB} is referred to as a fourth sidewall, and
a maximum value of a distance between the first sidewall and the line segment L_{1A} is referred to as a bulge B₁; a maximum value of a distance between the second sidewall and the line segment Lin is referred to as a bulge B₂; a maximum value of a distance between the third sidewall and the line segment L_{2A} is referred to as a bulge B₃; a maximum value of a distance between the fourth sidewall and the line segment L_{2B} is referred to as a bulge B₄; and a bulge having a maximum value among the bulges B₁ to B₄ is referred to as a bulge Bₘₐₓ,
this maximum bulge Bₘₐₓ is 5 μm or smaller.

### Embodiment 9

The method described in any one of Embodiments 1 to 8, wherein the glass substrate has a thickness in a range of 0.05 mm to 1.2 mm.

### Embodiment 10

A glass substrate with a through-hole comprising:
a glass substrate having a first surface and a second surface opposite to each other; and
at least one through-hole extending from the first surface of the glass substrate to the second surface thereof, wherein
the glass substrate has a thickness in a range of 0.05 mm to 1.2 mm,
the through-hole includes a first opening having a diameter φ₁ on the first surface of the glass substrate and includes a second opening having a diameter φ₂ on the second surface,
an absolute value of a difference Δφ between the diameter φ₁ of the first opening and the diameter φ₂ of the second opening is 5 μm or smaller,
in the through-hole, a position at which a size of a cross section perpendicular to an extension axis of the through-hole is a minimum is referred to as a constricted part,
in cross section of the through-hole along the extension axis thereof,
when one of ends of the first opening is referred to as a first end P_{1A}; the other end is referred to as a second end P_{1B}; an end of the second opening on the same side as the first end P_{1A} is referred to as a third end P_{2A}; an end of the second opening on the same side as the second end P_{1B} is referred to as a fourth end P_{2B}; an end of the constricted part on the same side as the first end P_{1A} is referred to as a fifth end P_{mA}; and an end of the constricted part on the same side as the second end P_{1B} is referred to as a sixth end P_{mB},
a line segment connecting the first end P_{1A} and the fifth end P_{mA} is referred to as a line segment L_{1A}; a line segment connecting the second end P_{1B} and the sixth end P_{mB} is referred to as a line segment Lin: a line segment connecting the third end P_{2A} and the fifth end P_{mA} is referred to as a line segment L_{2A}; and a line segment connecting the fourth end P_{2B} and the sixth end P_{mB} is referred to as a line segment L_{2B},
a perpendicular line is drawn from the first end P_{1A} toward inside of the glass substrate, and an angle formed between this perpendicular line and the line segment L_{1A} is referred to as a first upper taper angle θ_{f1u};
a perpendicular line is drawn from the second end P_{1B} toward inside of the glass substrate, and an angle formed between this perpendicular line and the line segment L_{1B} is referred to as a second upper taper angle θ_{2fu};
a perpendicular line is drawn from the third end P_{2A} toward inside of the glass substrate, and an angle formed between this perpendicular line and the line segment L_{2A} is referred to as a first lower taper angle θ_{1fd};
a perpendicular line is drawn from the fourth end P_{2B} toward inside of the glass substrate, and an angle formed between this perpendicular line and the line segment L_{2B} is referred to as a second lower taper angle θ_{2fd}, and
an average of θ_{1fu}, θ_{2fu}, θ_{1fd}, and θ_{2fd} is referred to as a taper angle θₐᵥₑ,
this taper angle θₐᵥₑ is smaller than 4°, in the cross section of the through-hole along the extension axis thereof,
when a sidewall part between the first end P_{1A} and the fifth end P_{mA} is referred to as a first sidewall; a sidewall part between the second end P_{1B} and the sixth end P_{mB} is referred to as a second sidewall; a sidewall part between the third end P_{2A} and the fifth end P_{mA} is referred to as a third sidewall; and a sidewall part between the fourth end P_{2B} and the sixth end P_{mB} is referred to as a fourth sidewall, and
a maximum value of a distance between the first sidewall and the line segment L_{1A} is referred to as a bulge B₁; a maximum value of a distance between the second sidewall and the line segment L_{1B} is referred to as a bulge B₂; a maximum value of a distance between the third sidewall and the line segment L_{2A} is referred to as a bulge B₃; a maximum value of a distance between the fourth sidewall and the line segment L_{2B} is referred to as a bulge B₄; and a bulge having a maximum value among the bulges B₁ to B₁ is referred to as a bulge Bₘₐₓ,
this maximum bulge Bₘₐₓ is 5 μm or smaller, and
when a distance from the first opening of the through-hole in a depth direction is represented by x (μm), and surface roughness (maximum height Rz) of a sidewall of the through-hole is represented by Q (μm), a relationship between Q and x can be approximated by

Q=mx+b Formula (1)
where m is an inclination in
(a) a range of −0.001 to −0.005, or
(b) a range of 0.001 to 0.005.

These embodiments can be combined as desirable by one of ordinary skill in the art. From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A method for manufacturing a glass substrate with a through-hole, comprising:
(1) a step of forming an initial through-hole in a glass substrate having a first surface and a second surface by applying laser light to the glass substrate from a first surface side thereof, the initial through-hole including a first initial opening on the first surface and including a second initial opening on the second surface;
(2) a step of performing first wet etching for the glass substrate at a first etching rate in a state in which a masking material is disposed so as to close one of the first and second initial openings of the initial through-hole that has a larger diameter, and thereby forming a first through-hole from the initial through-hole, the first etching rate being in a range of 0.04 μm/min to 0.20 μm/min; and
(3) a step of performing second wet etching for the glass substrate in a state in which the masking material has been removed, and thereby forming a second through-hole from the first through-hole.

2. The method according to claim 1, wherein the laser light is a CO₂ laser light.

3. The method according to claim 2, further comprising a step (4) of annealing the glass substrate between the step (1) and the step (2).

4. The method according to claim 2, wherein an etching rate in the second wet etching is between 0.07 μm/min and 2 μm/min.

5. The method according to claim 2, wherein an etchant used in the first wet etching is the same as or different from that used in the second wet etching.

6. The method according to claim 2, wherein
the second through-hole includes a first processed opening on the first surface of the glass substrate and includes a second processed opening on the second surface of the glass substrate, and
a difference Δφ (absolute value) between a diameter φ_{f1} of the first processed opening and a diameter φ_{f2} of the second processed opening is 5 μm or smaller.

7. The method according to claim 6, wherein
in the second through-hole, a position at which a size of a cross section perpendicular to an extension axis of the second through-hole is a minimum is referred to as a constricted part,
in cross section of the second through-hole along the extension axis thereof,
when one of ends of the first processed opening is referred to as a first end P_{1A}; the other end is referred to as a second end P_{1B}; an end of the second processed opening on the same side as the first end Pia is referred to as a third end P_{2A}; an end of the second processed opening on the same side as the second end P_{1B} is referred to as a fourth end P_{2B}; an end of the constricted part on the same side as the first end P_{1A} is referred to as a fifth end P_{mA}; and an end of the constricted part on the same side as the second end P_{1B} is referred to as a sixth end P_{mB},
a line segment connecting the first end P_{1A} and the fifth end P_{mA} is referred to as a line segment L_{1A}; a line segment connecting the second end P_{1B} and the sixth end P_{mB} is referred to as a line segment L_{1B}; a line segment connecting the third end P_{2A} and the fifth end P_{mA} is referred to as a line segment L_{2A}; and a line segment connecting the fourth end P_{2B} and the sixth end P_{mB} is referred to as a line segment L_{2B},
a perpendicular line is drawn from the first end P_{1A} toward inside of the glass substrate, and an angle formed between this perpendicular line and the line segment L_{1A} is referred to as a first upper taper angle θ_{1fu};
a perpendicular line is drawn from the second end P_{1B} toward inside of the glass substrate, and an angle formed between this perpendicular line and the line segment L_{1B} is referred to as a second upper taper angle θ_{2fu};
a perpendicular line is drawn from the third end P_{2A} toward inside of the glass substrate, and an angle formed between this perpendicular line and the line segment L_{2A} is referred to as a first lower taper angle θ_{1fd};
a perpendicular line is drawn from the fourth end P_{2B} toward inside of the glass substrate, and an angle formed between this perpendicular line and the line segment L_{2B} is referred to as a second lower taper angle θ_{2fd}, and
an average of θ_{1fu}, θ_{2fu}, θ_{1fd}, and θ_{2fd} is referred to as a taper angle θₐᵥₑ,
this taper angle θₐᵥₑ is smaller than 4°.

8. The method according to claim 7, wherein
in the cross section along the extension axis of the second through-hole,
when a sidewall part between the first end P_{1A} and the fifth end P_{mA} is referred to as a first sidewall; a sidewall part between the second end P_{1B} and the sixth end P_{mB} is referred to as a second sidewall; a sidewall part between the third end P_{2A} and the fifth end P_{mA} is referred to as a third sidewall; and a sidewall part between the fourth end P_{2B} and the sixth end P_{mB} is referred to as a fourth sidewall, and
a maximum value of a distance between the first sidewall and the line segment L_{1A} is referred to as a bulge B₁; a maximum value of a distance between the second sidewall and the line segment Lin is referred to as a bulge B₂; a maximum value of a distance between the third sidewall and the line segment L_{2A} is referred to as a bulge B₃; a maximum value of a distance between the fourth sidewall and the line segment L_{2B} is referred to as a bulge B₄: and a bulge having a maximum value among the bulges B₁ to B₄ is referred to as a bulge Bₘₐₓ,
this maximum bulge Bₘₐₓ is 5 μm or smaller.

9. The method according to claim 1, wherein the glass substrate has a thickness in a range of 0.05 mm to 1.2 mm.

10. A glass substrate with a through-hole comprising:
a glass substrate having a first surface and a second surface opposite to each other; and
at least one through-hole extending from the first surface of the glass substrate to the second surface thereof, wherein
the glass substrate has a thickness in a range of 0.05 mm to 1.2 mm,
the through-hole includes a first opening having a diameter φ₁ on the first surface of the glass substrate and includes a second opening having a diameter φ₂ on the second surface,
an absolute value of a difference Δφ between the diameter φ₁ of the first opening and the diameter φ₂ of the second opening is 5 μm or smaller,
in the through-hole, a position at which a size of a cross section perpendicular to an extension axis of the through-hole is a minimum is referred to as a constricted part,
in cross section of the through-hole along the extension axis thereof,
when one of ends of the first opening is referred to as a first end P_{1A}; the other end is referred to as a second end P_{1B}; an end of the second opening on the same side as the first end P_{1A} is referred to as a third end P_{2A}; an end of the second opening on the same side as the second end P_{1B} is referred to as a fourth end P_{2B}; an end of the constricted part on the same side as the first end P_{1A} is referred to as a fifth end P_{mA}; and an end of the constricted part on the same side as the second end P_{1B} is referred to as a sixth end P_{mB},
a line segment connecting the first end P_{1A} and the fifth end P_{mA} is referred to as a line segment L_{1A}; a line segment connecting the second end P_{1B} and the sixth end P_{mB} is referred to as a line segment L_{1B}; a line segment connecting the third end P_{2A} and the fifth end P_{mA} is referred to as a line segment L_{2A}; and a line segment connecting the fourth end P_{2B} and the sixth end P_{mB} is referred to as a line segment L_{2B},
a perpendicular line is drawn from the first end P_{1A} toward inside of the glass substrate, and an angle formed between this perpendicular line and the line segment L_{1A} is referred to as a first upper taper angle θ_{1fu};
a perpendicular line is drawn from the second end P_{1B} toward inside of the glass substrate, and an angle formed between this perpendicular line and the line segment L_{1B} is referred to as a second upper taper angle θ_{2fu};
a perpendicular line is drawn from the third end P_{2A} toward inside of the glass substrate, and an angle formed between this perpendicular line and the line segment L_{2A} is referred to as a first lower taper angle θ_{1fd};
a perpendicular line is drawn from the fourth end P_{2B} toward inside of the glass substrate, and an angle formed between this perpendicular line and the line segment L_{2B} is referred to as a second lower taper angle θ_{2rd}, and
an average of θ_{1fu}, θ_{2fu}, θ_{1fd}, and θ_{2fd} is referred to as a taper angle θₐᵥₑ,
this taper angle θₐᵥₑ is smaller than 4°,
in the cross section of the through-hole along the extension axis thereof,
when a sidewall part between the first end P_{1A} and the fifth end P_{mA} is referred to as a first sidewall; a sidewall part between the second end P_{1B} and the sixth end P_{mB} is referred to as a second sidewall; a sidewall part between the third end P_{2A} and the fifth end P_{mA} is referred to as a third sidewall; and a sidewall part between the fourth end P_{2B} and the sixth end P_{mB} is referred to as a fourth sidewall, and
a maximum value of a distance between the first sidewall and the line segment L_{1A} is referred to as a bulge B₁; a maximum value of a distance between the second sidewall and the line segment L_{1B} is referred to as a bulge B₂; a maximum value of a distance between the third sidewall and the line segment L_{2A} is referred to as a bulge B₃; a maximum value of a distance between the fourth sidewall and the line segment L_{2B} is referred to as a bulge B₄: and a bulge having a maximum value among the bulges B₁ to B₄ is referred to as a bulge Bₘₐₓ,
this maximum bulge Bₘₐₓ is 5 μm or smaller, and
when a distance from the first opening of the through-hole in a depth direction is represented by x (μm), and surface roughness (maximum height Rz) of a sidewall of the through-hole is represented by Q (μm), a relationship between Q and x can be approximated by
Q=mx+b Formula (1)
where m is an inclination in
(a) a range of −0.001 to −0.005, or
(b) a range of 0.001 to 0.005.
